(19) United States
(12) Patent Application Publication
(10) Pub. No.: US 2013/0009275 A1
(43) Pub. Date: Jan. 10, 2013

(54) SEMICONDUCTOR INTEGRATED CIRCUIT DEVICE AND TERMINAL STRUCTURE OF STANDARD CELL

(75) Inventors: Atsushi TAKAHATA, Osaka (JP); Hiroyuki Uehara, Hyogo (JP)

(73) Assignee: Panasonic Corporation, Osaka (JP)

(21) Appl. No.: 13/621,055

(22) Filed: Sep. 15, 2012

Related U.S. Application Data
(63) Continuation of application No. PCT/JP2011/000981, filed on Feb. 22, 2011.

(30) Foreign Application Priority Data
May 17, 2010 (JP) 2010-113537

(51) Int. Cl. H01L 25/00; H01L 27/04

(52) U.S. Cl. 257/499; 327/565; 257/E27.01

(57) ABSTRACT

A semiconductor integrated circuit device includes a first standard cell and a second standard cell adjacent to the first standard cell in a first direction. An interconnect is provided to extend in the first direction to electrically connect input and output terminal portions, which extend in a second direction orthogonal to the first direction. The output terminal portion extends in a first sub-direction of the second direction from a region connected to the interconnect, but not in a second sub-direction opposite to the first sub-direction. The input terminal portion extends in a second sub-direction of the second direction from a region connected to the interconnect, but not in the first sub-direction.

### CROSS-REFERENCE TO RELATED APPLICATION

This is a continuation of PCT International Application PCT/JP2011/000981 filed on Feb. 22, 2011, which claims priority to Japanese Patent Application No. 2010-113537 filed on May 17, 2010. The disclosures of these applications including the specifications, the drawings, and the claims are hereby incorporated by reference in their entirety.

### BACKGROUND

The present disclosure relates to interconnect structures of terminals of standard cells used in semiconductor integrated circuit devices.

Conventionally, the layout of a semiconductor integrated circuit has been designed by arranging circuit components called standard cells. Standard cells serve as functional blocks such as NAND gates, NOR gates, INV gates, flip-flops (FFs), etc. The form of internal interconnection is designed in advance. Usually, in designing a semiconductor integrated circuit of a standard cell type, standard cells registered in a library are arranged in a row and interconnection is made using an automatic place and route tool, thereby providing a desired semiconductor integrated circuit. Japanese Patent Publication No. H02-001952 and Japanese Patent Publication No. 2002-016144 show example standard cells having distinctive terminal structures.

Recent techniques of manufacturing semiconductors have been significantly progressed, and miniaturization has been increasingly advanced. The miniaturization is achieved by dramatic development in miniaturized pattern formation techniques such as masking, optical lithography, etching, etc. In the period when pattern sizes were sufficiently large; a mask pattern exactly reflecting a design pattern was prepared and transferred on a wafer by a projection optical system, and the base is etched, thereby forming a pattern almost exactly as designed on the wafer. However, as miniaturization of patterns progresses, it is becoming difficult to exactly form a pattern in each process, and the final finished size is not as originally designed.

In order to solve the problem, preparing a mask pattern different form a design pattern is becoming very important in view of conversion differences in each process so that the final finished size is equal to the size of the design pattern.

On the other hand, in recent years, the value of k1 (k1=W/(NA/λ), where W is the size of a design pattern, λ is the exposure wavelength of an exposure apparatus, and the numerical aperture of a lens used in the exposure apparatus) has been increasingly reduced in lithography with further miniaturization. As a result, what is called an optical proximity effect (OPE) tends to further increase, and thus, the load of optical proximity correction (OPC) for correcting the OPE largely increases.

If miniaturization further progresses, correction by the OPC would not be prefect, the difference between a design pattern and the final finished size increases. Such a design pattern in which mask correction by the OPC is difficult to perform is called a hot spot. Japanese Patent Publication No. 2008-258425 shows an example form of interconnection free from any hot spot.

### SUMMARY

FIG. 13A illustrates the relationship between a design pattern and an actual finished form of terminals and an interconnect. In FIG. 13A, an output terminal portion 101 and an input terminal portion 102 are arranged in parallel. An interconnect 103 is provided in the same interconnect layer to connect the output terminal portion 101 to the input terminal portion 102. That is, the cell terminals and the interconnect, which are provided in the same interconnect layer, form a U-shape, i.e., a recessed shape.

Unless performing OPC, the final finished form of such a recessed interconnection is significantly different from the design pattern due to interference of light. Specifically, as indicated by the thick solid lines, a recess between the output terminal portion 101 and the interconnect 103 expands outside (in a direction a1). Similarly, a recess between the input terminal portion 102 and the interconnect 103 expands outside (in direction a2). Thus, in the OPC, the design pattern needs to be corrected in a direction b1 opposite to the direction a1 and a direction b2 opposite to the direction a2.

FIG. 13B is an enlarged view of a portion X in FIG. 13A and illustrates a design pattern 105 after OPC and a final finished form 106. As shown in FIG. 13B, the OPC prevents a recess between the input terminal portion 102 and the interconnect 103 from expanding outside. However, the terminal width of the input terminal portion 102 in the final finished form is reduced, as compared to the original design pattern before the OPC. The reduced terminal width is referred to as a first hot spot in the present specification. In order to reduce occurrence of the first hot spot, increasing the terminal widths of the input terminal portion 102 and the output terminal portion 101 are considered in the design pattern 105 after the OPC. However, the input terminal portion 102 faces the output terminal portion 101 in the horizontal direction of the drawing. Thus, if the terminal widths are increased in the design pattern, the input terminal portion 102 and the output terminal portion 101 tend to interfere with each other. As shown in FIG. 13A, where another interconnect 104 is adjacent to the interconnect structure, increasing the terminal width is actually difficult. That is, a first hot spot tends to occur in a recessed interconnection form.

FIG. 14 illustrates the relationship between a design pattern after OPC correction and an actual finished form of terminals and an interconnect. In FIG. 14, an output terminal portion 111 and an input terminal portion 112 are arranged in shifted positions in the vertical direction of the drawing. An interconnect 113 is provided in the same interconnect layer to connect the output terminal portion 111 to the input terminal portion 112. That is, the cell terminals and the interconnect, which are provided in the same interconnect layer, form a crank shape.

In FIG. 14, reference numeral 115 denotes the design pattern after the OPC correction, and 116 denotes the final finished form. As shown in FIG. 14, the OPC prevents a recess between the output terminal portion 111 and the interconnect 113 from expanding outside, and a recess between the input terminal portion 112 and the interconnect 113 from expanding outside. However, the interconnect width of the interconnect 113 in the final finished form is reduced as compared to the original design pattern before the OPC. The reduced interconnect width is referred to as a second hot spot in the present specification.

Conventionally, where an interconnection form being a hot spot is detected in a design pattern, layout has been redesigned not to create such an interconnection form. That is, if a hot spot exists in the layout of a semiconductor integrated circuit device, designing turns back, thereby increasing the turn-around time (TAT) for designing the semiconductor integrated circuit.

If the first and second hot spots described above exist, the thickness of the final finished interconnection form is partially reduced. In some cases, disconnection may occur, thereby reducing the yield of the semiconductor integrated circuit device.

In view of the foregoing, it is an objective of the present disclosure to provide an interconnect structure of terminals of standard cells, in which a hot spot is less likely to occur, which may increase the design TAT and reduce the yield of a semiconductor integrated circuit device.

According to a first aspect, a semiconductor integrated circuit device includes a first standard cell; a second standard cell adjacent to the first standard cell in a first direction; an output terminal portion provided as an output terminal of the first standard cell to extend in a second direction orthogonal to the first direction; an input terminal portion provided as an input terminal of the second standard cell to extend in the second direction; and an interconnect provided to extend in the first direction to electrically connect the output terminal portion to the input terminal portion. The output terminal portion, the input terminal portion, and the interconnect are formed in a same metal interconnect layer. The output terminal portion extends in a first sub-direction of the second direction from a region connected to the interconnect, but not in a second sub-direction opposite to the first sub-direction. The input terminal portion extends in the second sub-direction of the second direction from a region connected to the interconnect, but not in the first sub-direction.

According to the first aspect, in the semiconductor integrated circuit device, the output terminal portion and the input terminal portions, which extend in the same direction, are connected together by the interconnect, which is formed in the same interconnect layer as the terminal portions and extends in the direction orthogonal to the extending direction of the terminal portions. The output terminal portion extends only in the one direction from the region connected to the interconnect, while the input terminal portion extends only in the other direction from the region connected to the interconnect. That is, the output terminal portion, the interconnect, and the input terminal portion do not form a U-shape, i.e. a recessed shape, thereby avoiding an interconnection form which is likely to cause the above-described first hot spot. This reduces regress in designing or mitigates reduction in the manufacturing yield due to disconnection. According to a second aspect, a terminal structure of a standard cell includes an input terminal portion provided as an input terminal of the standard cell to extend in a first direction; and an output terminal portion provided as an output terminal of the standard cell to extend in the first direction. The input terminal portion overlaps the output terminal portion in a region as viewed along a second direction orthogonal to the first direction. The input terminal portion extends in a first sub-direction of the first direction from the overlapping region, but not in a second sub-direction opposite to the first sub-direction. The output terminal portion extends in the second sub-direction of the first direction from the overlapping region, but not in the first sub-direction.

According to the second aspect, in the standard cell, the output terminal portion and the input terminal portion, which extend in the first direction, overlap each other as viewed along the second direction orthogonal to the first direction. The input terminal portion extends only in the one direction from the overlapping region, while the output terminal portion extends only in the other direction from the overlapping region. Standard cells each having such a terminal structure are arranged in the second direction, thereby avoiding an interconnection form which is likely to cause the above-described first hot spot. This reduces regress in designing or mitigates reduction in the manufacturing yield due to disconnection.

According to a third aspect, a semiconductor integrated circuit device including a standard cell; an output terminal portion provided as an output terminal of the standard cell to extend in a first direction; an input terminal portion provided as an input terminal of the standard cell to extend in the first direction; a first interconnect connected to the output terminal portion, and provided to extend in a first sub-direction of a second direction orthogonal to the first direction from the output terminal portion; and a second interconnect connected to the output terminal portion, and provided to extend in a second sub-direction of the second direction, which is opposite to the first sub-direction, from the output terminal portion. The output terminal portion, the input terminal portion, and the first and second interconnects are formed in a same metal interconnect layer. The first interconnect does not overlap the second interconnect as viewed along the second direction. A terminal width of the output terminal portion between a portion connected to the first interconnect and a portion connected to the second interconnect is greater than a terminal width of the input terminal portion.

According to the third aspect, the output terminal portion extending in the first direction is connected to the first interconnect extending in the second direction of the first sub-direction, and to the second interconnect extending in the second sub-direction opposite to the first sub-direction. As viewed along the second direction, the first interconnect does not overlap the second interconnect. That is, the output terminal portion and the first and second interconnects form a crank-shaped interconnect structure, i.e., an interconnect structure which is likely to cause the above-described second hot spot. However, since the terminal width of the output terminal portion is greater than the terminal width of the input terminal portion, occurrence of the second hot spot can be reduced. This reduces regress in designing or mitigates reduction in the manufacturing yield due to disconnection.

According to a fourth aspect, a semiconductor integrated circuit device includes a first standard cell; a second standard cell adjacent to the first standard cell in a first direction; an output terminal portion provided as an output terminal of the first standard cell to extend in a second direction orthogonal to the first direction; an input terminal portion provided as an input terminal of the second standard cell to extend in the second direction; and an interconnect provided to extend in the first direction to electrically connect the output terminal portion to the input terminal portion. The output terminal portion, the input terminal portion, and the interconnect are formed in a same metal interconnect layer. The output terminal portion is located in a same position and has a same length as the input terminal portion in the second direction. The interconnect has an interconnect width which is equal to lengths of the output terminal portion and the input terminal portion, and is located in a same position as the output terminal portion and the input terminal portion in the second direction.

According to the fourth aspect, in the semiconductor integrated circuit device, the output terminal portion and the input terminal portion, which extend in the same direction, are connected together by the interconnect, which is formed in the same interconnect layer as the terminal portions and extends in the direction orthogonal to the extending direction of the terminal portions. The interconnect has the interconnect width which is equal to the lengths of the output terminal portion and the input terminal portion. The interconnect is located in the same position as the output terminal portion and the input terminal portion in the extending direction of the output terminal portion and the input terminal portion. That is, the interconnect structure including the output terminal, the interconnect, and the input terminal portion does not form a U-shape, i.e., a recessed shape, or a crank shape, thereby avoiding an interconnection form which is likely to cause the above-described first and second hot spots. This reduces regress in designing or mitigates reduction in the manufacturing yield due to disconnection.

The present disclosure provides an interconnect structure of terminals in a standard cell, which is less likely to cause the above-described first and second hot spots. This reduces regress in designing, thereby reducing the TAT and disconnection. As a result, the manufacturing yield can be improved.

### BRIEF DESCRIPTION OF THE DRAWINGS

FIG. 1 is a plan view illustrating the structure of cell terminals and an interconnect in a semiconductor integrated circuit device according to a first embodiment.

FIG. 2 is a plan view illustrating the structure of cell terminals and an interconnect in a semiconductor integrated circuit device according to a second embodiment.

FIG. 3A is a plan view illustrating a terminal structure of a standard cell according to a third embodiment. FIG. 3B is a plan view illustrating the structure of cell terminals and an interconnect in a semiconductor integrated circuit device using the standard cell of FIG. 3A.

FIG. 4 is a plan view illustrating a terminal structure of a standard cell according to a fourth embodiment.

FIG. 5 is a plan view illustrating an example structure of cell terminals and an interconnect in a semiconductor integrated circuit device according to a fifth embodiment.

FIG. 6 illustrates an example internal structure associated with an output terminal portion of a standard cell shown in FIG. 5.

FIG. 7 is a plan view illustrating another example structure of cell terminals and an interconnect in the semiconductor integrated circuit device according to the fifth embodiment.

FIG. 8 is a plan view illustrating an example structure of cell terminals and an interconnect in a semiconductor integrated circuit device according to a sixth embodiment.

FIG. 9 illustrates an example layout structure of an actual semiconductor integrated circuit device where the interconnect structure according to the embodiments is used in standard cells.

FIGS. 10A-10D illustrate the detailed structure of some of the standard cells shown in FIG. 9. FIG. 10A is a logical diagram. FIG. 10B is a top view. FIGS. 10C and 10D are cross-sectional views.

FIGS. 11A-11C illustrate the structure of one of the standard cell shown in FIG. 9. FIG. 11A is a logical diagram. FIG. 11B is a top view. FIGS. 11C and 11D are cross-sectional views.

FIG. 12 illustrates another example layout structure of an actual semiconductor integrated circuit device where the interconnect structure according to the embodiments is used in standard cells.

FIGS. 13A and 13B illustrate occurrence of a first hot spot.

FIG. 14 illustrates occurrence of a second hot spot.

### DETAILED DESCRIPTION

Embodiments will be described hereinafter with reference to the drawings.

### First Embodiment

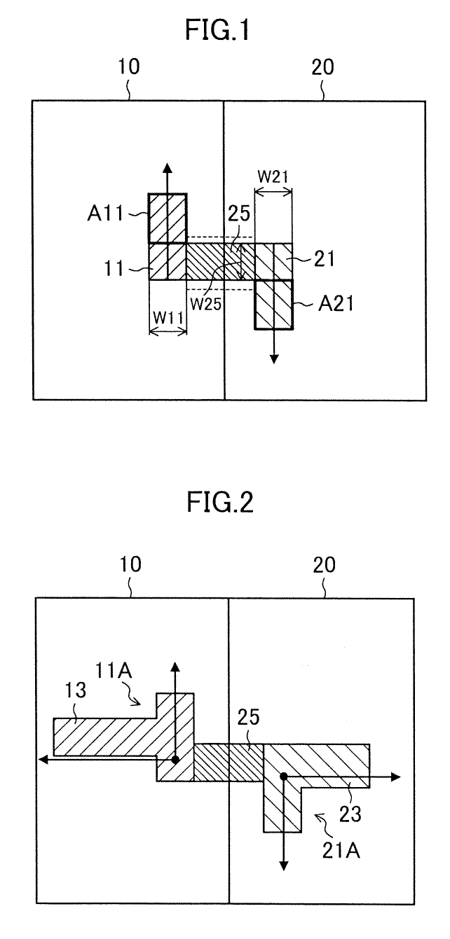

FIG. 1 is a plan view illustrating the structure of cell terminals and an interconnect in a semiconductor integrated circuit device according to a first embodiment. In FIG. 1, a first standard cell 10 is adjacent to a second standard cell 20 in the horizontal direction (a first direction) of the drawing. An output terminal portion 11 is provided in the first standard cell 10 to extend in the vertical direction (a second direction) of the drawing. The output terminal portion 11 functions as an output terminal of the first standard cell 10. An input terminal portion 21 is provided in the second standard cell 20 to extend in the vertical direction of the drawing. The input terminal portion 21 functions as an input terminal of the second standard cell 20.

An interconnect 25 is provided to extend in the horizontal direction of the drawing to electrically connect the output terminal portion 11 to the input terminal portion 21. The output terminal portion 11, the input terminal portion 21, and the interconnect 25 are formed in the same metal interconnect layer. Using a different interconnect layer to form the interconnect layer to electrically connect the output terminal portion 11 to the input terminal portion 21 may be also considered. In this case, however, the interconnect length of the interconnect increases and a contact needs to be provided to connect the upper and lower interconnect layers. Therefore, in order to reduce the interconnect length, interconnection in the same interconnect layer is often used, for example, in an automatic place and route tool.

The output terminal portion 11 extends upward (in a first sub-direction) in the vertical direction of the drawing from the region connected to the interconnect 25. The output terminal portion 11 does not extend downward (in a second sub-direction). The input terminal portion 21 extends downward in the vertical direction of the drawing from the region connected to the interconnect 25. The input terminal portion 21 does not extend upward. That is, only the output terminal portion 11 extends above the interconnect 25, and only the input terminal portion 21 extends below the interconnect 25. In other words, the portion (a region A11) of the output terminal portion 11, which extends from the region connected to the interconnect 25, does not face the input terminal portion 21 in the horizontal direction of the drawing. Similarly, the portion (a region A21) of the input terminal portion 21, which extends from the region connected to the interconnect 25 does not face the output terminal portion 11 in the horizontal direction of the drawing.

As such, in this embodiment, the cell terminals and the interconnect, which are formed in the same interconnect layer, do not form a U-shape, i.e., a recessed shape. That is, an interconnection form which is likely to cause the above-described first hot spot can be avoided in advance. This reduces regress in designing, or mitigates reduction in the manufacturing yield due to disconnection. In the case of the recessed interconnect structure, for example, a mask of the output terminal portion is difficult to expand, since interference with the facing interconnect portion, i.e., the input terminal portion, tends to occur. By contrast, in this embodiment, no facing interconnect portion exists in the output terminal portion 11 and the input terminal portion 21, thereby easily expanding the mask.

FIG. 1 illustrates a crank-shaped interconnect structure, i.e., an interconnect structure which is likely to cause the above-described second hot spot. In order to reduce occurrence of the second hot spot, as indicated by the dashed line, the interconnect width W25 of the interconnect 25 is preferably greater than or equal to the terminal width W11 of the output terminal portion 11, and the terminal width W21 of the input terminal portion 21.

While in FIG. 1, the lower side of the output terminal portion 11 is located in the substantially same straight line as the lower side of the interconnect 25, the structure is not limited thereto. For example, the lower side of the output terminal portion 11 may be located between the upper side and the lower side of the interconnect 25, and the left side of the interconnect 25 may extend to the position of the left side of the output terminal portion 11. Similarly, while the upper side of the input terminal portion 21 is located in the substantially same straight line as the upper side of the interconnect 25, the structure is not limited thereto. For example, the upper side of the input terminal portion 21 may be located between the upper and lower sides of an interconnect 25, and the right side of the interconnect 25 may extend to the position of the right side of the input terminal portion 21.

The output terminal portion 11 is preferably an output terminal of the first standard cell 10, which is closest to the second standard cell 20. The input terminal portion 21 is preferably an input terminal of the second standard cell 20, which is closest to the first standard cell 10.

### Second Embodiment

FIG. 2 is a plan view illustrating the structure of cell terminals and an interconnect in a semiconductor integrated circuit device according to a second embodiment. In FIG. 2, the same reference characters as those shown in FIG. 1 are used to represent equivalent elements, and detailed explanation thereof will be omitted.

In FIG. 2, similar to FIG. 1, the portion of an output terminal portion 11A, which extends upward from a region connected to an interconnect 25, does not face an input terminal portion 21A in the horizontal direction of the drawing. The portion of the input terminal portion 21A, which extends downward from a region connected to the interconnect 25 does not face the output terminal portion 11A in the horizontal direction of the drawing. As such, in this embodiment, the cell terminals and the interconnect, which are formed in the same interconnect layer, do not form a U-shape, i.e., a recessed shape. An interconnection form which is likely to cause the above-described first hot spot can be avoided in advance.

In this embodiment, the output terminal portion 11A has a protrusion 13 formed to protrude in the direction (to the left) opposite to the interconnect 25 in the horizontal direction of the drawing. The input terminal portion 21A has a protrusion 23 formed to protrude in the direction (to the right) opposite to the interconnect 25 in the horizontal direction of the drawing.

For example, an automatic place and route tool usually tends to facilitate interconnection between terminals and reduce the congestion of the interconnection with an increase in the configuration area of an input terminal or an output terminal of a standard cell. Thus, as in this embodiment, the protrusion 13 is provided in the output terminal portion 11A, and the protrusion 23 is provided in the input terminal portion 21A, thereby increasing the areas of the terminal portions. As a result, there is the advantage of reducing the congestion of the interconnection between the terminals. In addition, since the protrusions 13 and 23 are provided to protrude in the horizontal direction of the drawing, the advantage of reducing occurrence of a hot spot in the interconnect structure in the first embodiment is maintained.

While in this embodiment, both the output terminal portion and the input terminal portion have the protrusions, the structure is not limited thereto. Either one of the output terminal portion or the input terminal portion may have a protrusion formed to protrude in the direction opposite to the interconnect. In this case, an advantage similar to this embodiment can be obtained.

### Third Embodiment

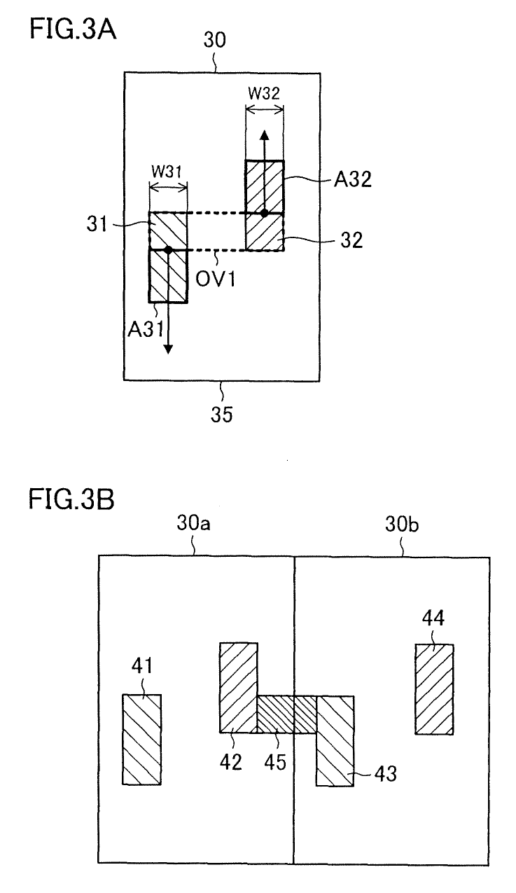

FIG. 3A is a plan view illustrating a terminal structure of a standard cell according to a third embodiment. In FIG. 3A, an input terminal portion 31 and an output terminal portion 32 are provided in a standard cell 30 to extend in the vertical direction (a first direction) of the drawing. The input terminal portion 31 functions as an input terminal of the standard cell 30. The output terminal portion 32 functions as an output terminal of the standard cell 30.

The input terminal portion 31 overlaps the output terminal portion 32 in a region (an overlapping region OV1) as viewed along the horizontal direction (a second direction) of the drawing. The input terminal portion 31 extends downward (in a first sub-direction) in the vertical direction of the drawing from the overlapping region OV1. The input terminal portion 31 does not extend upward (in a second sub-direction). The output terminal portion 32 extends upward (in the second sub-direction) in the vertical direction of the drawing from the overlapping region OV1. The output terminal portion 32 does not extend downward (in the first sub-direction). That is, only the input terminal portion 31 extends below the overlapping region OV1, and only the output terminal portion 32 extends above the overlapping region OV1. In other words, the portion (a region A31) of the input terminal portion 31, which extends from the overlapping region OV1, does not face the output terminal portion 32 in the horizontal direction of the drawing. Similarly, the portion (a region A32) of the output terminal portion 32, which extends from the overlapping region OV1, does not face the input terminal portion 31 in the horizontal direction of the drawing. The input terminal portion 31 faces the output terminal portion 32 only in the overlapping region OV1.

FIG. 3B is a plan view illustrating, the structure of cell terminals and an interconnect in a semiconductor integrated circuit device using, the standard cell of FIG. 3A. In FIG. 3B, a first standard cell 30a is adjacent to a second standard cell 30b in the horizontal direction of the drawing. Each of the first standard cell 30a and the second standard cell 30b has a terminal structure similar to the standard cell 30 of FIG. 3A. Specifically, the first standard cell 30a has an input terminal portion 41 and an output terminal portion 42 similar to FIG. 3A. The second standard cell 30b has an input terminal portion 43 and an output terminal portion 44 similar to FIG. 3A. The first standard cell 30a and the second standard cell 30b may have the same functions or different functions.

An interconnect 45 is provided by, for example, an automatic place and route tool. The interconnect 45 extends in the horizontal direction of the drawing to electrically connect the output terminal portion 42 of the first standard cell 30a to the input terminal portion 43 of the second standard cell 30b. The interconnect 45 is formed in the same metal interconnect layer as the output terminal portion 42 and the input terminal portion 43.

As shown in FIG. 3B, the cell terminals and the interconnect, which are formed in the same interconnect layer, do not form a U-shape, i.e., a recessed shape. That is, with use of a standard cell having the terminal structure shown in FIG. 3A, an interconnection form which is likely to cause the above-described first hot spot can be avoided in advance. This reduces regress in designing, or mitigates reduction in the manufacturing yield due to disconnection.

Depending on the structure of a standard cell, one or both of the input terminal and the output terminal is/are provided in a plural number. In this case, if the outermost input terminal in the standard cell and the outermost output terminal on the opposite side have the relationship shown in FIG. 3A, the advantage of this embodiment can be obtained. Specifically, the input terminal portion 31 is preferably the input terminal closest to one side of the frame (e.g., on the left side of the frame in the drawing) in the horizontal direction of the drawing. The output terminal portion 32 is preferably the output terminal closest to the other side of the frame (e.g., on the right side of the frame in the drawing) in the horizontal direction of the drawing.

### Fourth Embodiment

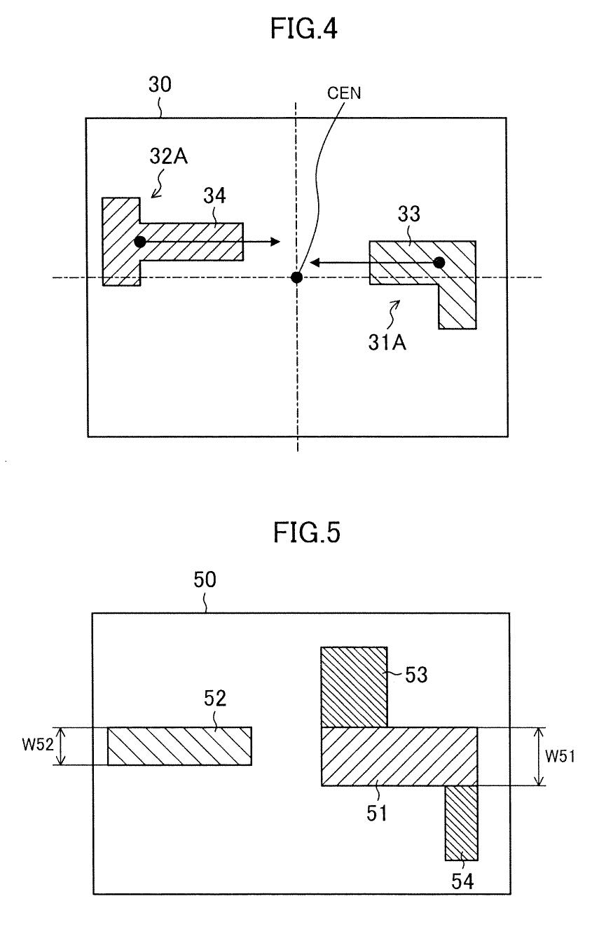

FIG. 4 is a plan view illustrating a terminal structure of a standard cell according to a fourth embodiment. In FIG. 4, the same reference characters as those shown in FIG. 3A are used to represent equivalent elements, and detailed explanation thereof will be omitted.

In FIG. 4, similar to FIG. 3A, an input terminal portion 31A overlaps an output terminal portion 32A as viewed along the horizontal direction of the drawing. The portion of the input terminal portion 31A, which extends downward from the overlapping region, does not face the output terminal portion 32A in the horizontal direction of the drawing. The portion of the output terminal portion 32A, which extends upward from the overlapping region, does not face the input terminal portion 31A in the horizontal direction of the drawing. That is, with use of a standard cell having the terminal structure shown in FIG. 4, a U-shaped, i.e., a recessed interconnection form, which is likely to cause the above-described first hot spot, can be avoided in advance.

In this embodiment, the input terminal portion 31A has a protrusion 33 formed to protrude toward the center CEN of the standard cell 30 (to the left side) in the horizontal direction of the drawing. The output terminal portion 32A has a protrusion 34 formed to protrude toward the center CEN of the standard cell 30 (to the right side) in the horizontal direction of the drawing.

For example, in an automatic place and route tool, interconnection between terminals is usually facilitated and the congestion of the interconnection tends to be reduced with an increase in the configuration area of an input terminal or an output terminal of a standard cell. Thus, as in this embodiment, the protrusion 33 is provided in the input terminal portion 31A, and the protrusion 34 is provided in the output terminal portion 32A, thereby increasing the areas of the terminal portions. As a result, there is the advantage of reducing the congestion of the interconnection between the terminals. In addition, since the protrusions 33 and 34 are provided to protrude in the horizontal direction of the drawing, the advantage of reducing occurrence of a hot spot in the cell terminal structure in the third embodiment is maintained.

While in this embodiment, both the output terminal portion and the input terminal portion have the protrusions, the structure is not limited thereto. Either one of the output terminal portion or the input terminal portion may have a protrusion formed to protrude toward the center of the standard cell. In this case, an advantage similar to this embodiment can be obtained.

### Fifth Embodiment

FIG. 5 is a plan view illustrating the structure of cell terminals and an interconnect in a semiconductor integrated circuit device according to a fifth embodiment. In FIG. 5 an output terminal portion 51 and an input terminal portion 52 are provided in a standard cell 50 to extend in the horizontal direction (a first direction) of the drawing. The output terminal portion 51 functions as an output terminal of the standard cell 50. The input terminal portion 52 functions as an input terminal of the standard cell 50.

The output terminal portion 51 is connected to a first interconnect 53 and a second interconnect 54. These interconnects 53 and 54 are arranged, for example, by an automatic place and route tool, where the fanout number of the output terminal portion 51 is two or more. The first interconnect 53 extends upward (in a first sub-direction) from the output terminal portion 51 in the vertical direction (i.e., the second direction) of the drawing. On the other hand, the second interconnect 54 extends downward (in a second sub-direction) from the output terminal portion 51 in the vertical direction of the drawing. The output terminal portion 51, the input terminal portion 52, and the first and second interconnects 53 and 54 are formed in the same metal interconnect layer.

The first interconnect 53 does not overlap the second interconnects 54 as viewed along the vertical direction of the drawing. That is, the output terminal portion 51 and the first and second interconnects 53 and 54 form a crank-shaped interconnect structure, i.e., an interconnect structure which is likely to cause the above-described second hot spot. In order to reduce the occurrence of the second hot spot, the terminal width W51 of the output terminal portion 51 is set great. In this embodiment, the terminal width W51 of the output terminal portion 51 between the portion connected to the first interconnect 53 and the portion connected to the second interconnect 54 is greater than the terminal width W52 of the input terminal portion 52. Thus, occurrence of the second hot spot can be reduced. This reduces regress in designing, and mitigates reduction in the manufacturing yield due to disconnection.

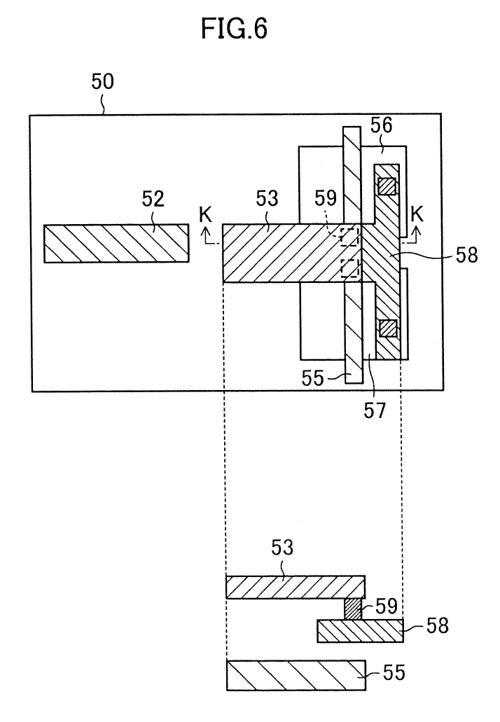

FIG. 6 illustrates an example internal structure associated with an output terminal portion 53 of the standard cell 50. As shown in FIG. 6, transistors 56 and 57 sharing a gate electrode 55 are adjacent to the frame of the standard cell 50. The output terminal portion 53 is connected via a contact 59 to an intra-cell interconnect 58 connected to drains of the transistors 56 and 57.

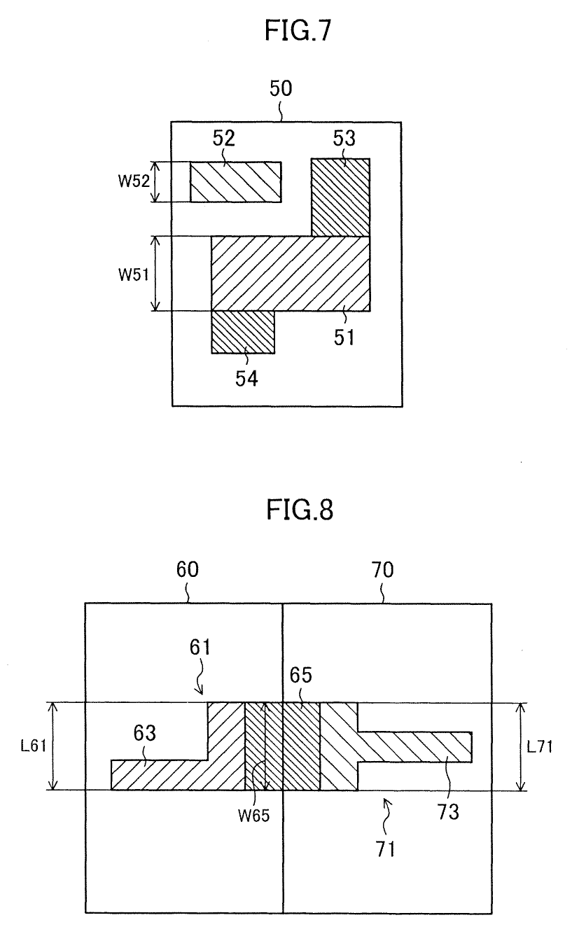

FIG. 7 is a plan view illustrating another example structure of cell terminals and an interconnect in the semiconductor integrated circuit device according to this embodiment. In FIG. 7, the same reference characters as those shown in FIG. 5 are used to represent equivalent elements, and the explanation thereof will be omitted. In FIG. 7, the output terminal portion 51 overlaps the input terminal portion 52 as viewed along the vertical direction of the drawing. In other respects, FIG. 7 is similar to FIG. 5. Specifically, the output terminal portion 51 and the first and second interconnects 53 and 54 form a crank-shaped interconnect structure, i.e., an interconnect structure which is likely to cause the above-described second hot spot. The terminal width W51 of the output terminal portion 51 between the portion connected to the first interconnect 53 and the portion connected to the second interconnect 54 is greater than the terminal width W52 of the input terminal portion 52. Similar to FIG. 5, since occurrence of the second hot spot can be reduced, regress in designing can be reduced or reduction in the manufacturing yield due to disconnection can be mitigated.

### Sixth Embodiment

FIG. 8 is a plan view illustrating an example structure of cell terminals and an interconnect in a semiconductor integrated circuit device according to a sixth embodiment. In FIG. 8, a first standard cell 60 is adjacent to a second standard cell 70 in the horizontal direction (a first direction) of the drawing. An output terminal portion 61 is provided in the first standard cell 60 to extend in the vertical direction (a second direction) of the drawing. The output terminal portion 61 functions as an output terminal of the first standard cell 60. An input terminal portion 71 is provided in the second standard cell 70 to extend in the vertical direction of the drawing. The input terminal portion 71 functions as an input terminal of the second standard cell 70.

An interconnect 65 extends in the horizontal direction of the drawing to electrically connect the output terminal portion 61 to the input terminal portion 71. The output terminal portion 61, the input terminal portion 71, and the interconnect 65 are formed in the same metal interconnect layer. The interconnect 65 is provided by an automatic place and route tool, for example.

The output terminal portion 61 is located in a same position and has a same length as the input terminal portion 71 in the vertical direction of the drawing. The interconnect width W65 of the interconnect 65 is equal to the length L61 of the output terminal portion 61, and the length L71 of the input terminal portion 71. The interconnect 65 is located in a same position as the output terminal portion 61 and the input terminal portion 71 in the vertical direction of the drawing. In other words, the output terminal portion 61, the input terminal portion 71, and the interconnect 65 overlap almost exactly as viewed along the horizontal direction of the drawing.

As such, in this embodiment, the cell terminals and the interconnect, which are formed in the same interconnect layer, do not form a U-shape, i.e. a recessed shape, or a crank shape. That is, the cell terminals and the interconnect do not form an interconnection form which is likely to cause the above-described first hot spot and the second hot spot. Thus, occurrence of the hot spots can be reduced. This reduces regress in designing or mitigates reduction in the manufacturing yield due to disconnection.

In this embodiment, the output terminal portion 61 has a protrusion 63 formed to protrude in the direction (to the left) opposite to the interconnect 65 in the horizontal direction of the drawing. The input terminal portion 71 has a protrusion 73 formed to protrude in the direction (to the right) opposite to the interconnect 65 in the horizontal direction of the drawing. This increases the areas of the terminals, thereby obtaining the advantage of reducing the congestion of interconnection between the terminals. In addition, since the protrusions 63 and 73 protrude in the horizontal direction of the drawing, the advantage of reducing occurrence of a hot spot is maintained.

While in this embodiment, both the output terminal portion and the input terminal portion have the protrusions, the structure is not limited thereto. Either one of the output terminal portion or the input terminal portion may have a protrusion formed to protrude in the direction opposite to the interconnect. In this case, an advantage similar to this embodiment can be obtained.

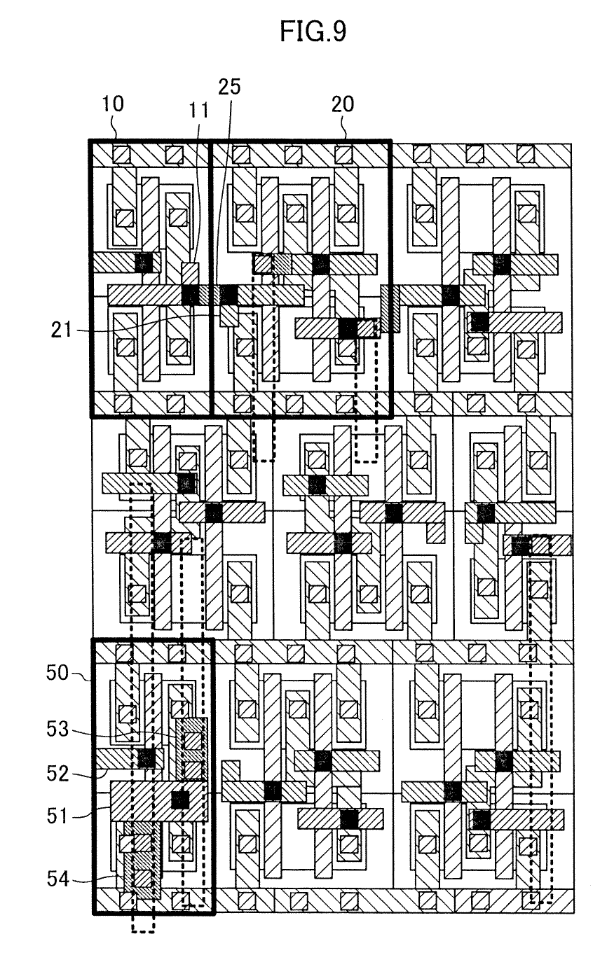

FIG. 9 illustrates an example layout structure of an actual semiconductor integrated circuit device where the interconnect structure according to the embodiments is used in standard cells. In FIG. 9, standard cells indicated by rectangular frames are arranged in a matrix and form a predetermined logic. The standard cells employing the above-described embodiments are surrounded by thick frames. Specifically, two left standard cells 10 and 20 in the uppermost row employ the interconnect structure shown in FIG. 1. The left standard cell 50 in the lowermost row employs the interconnect structure shown in FIG. 7. In FIG. 9, the same reference characters as those shown in FIGS. 1 and 7 are used to represent equivalent elements.

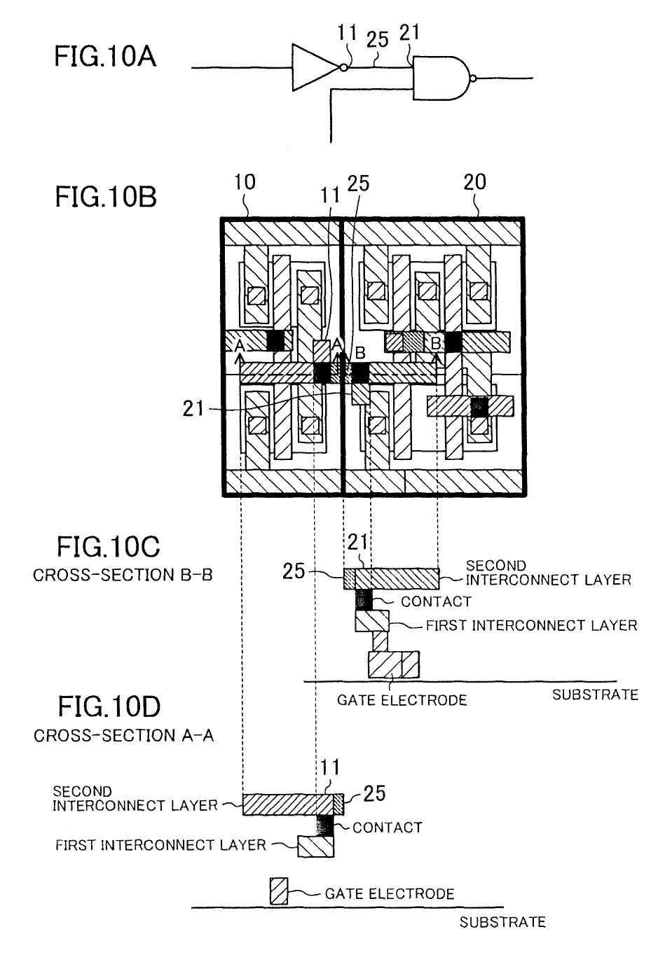

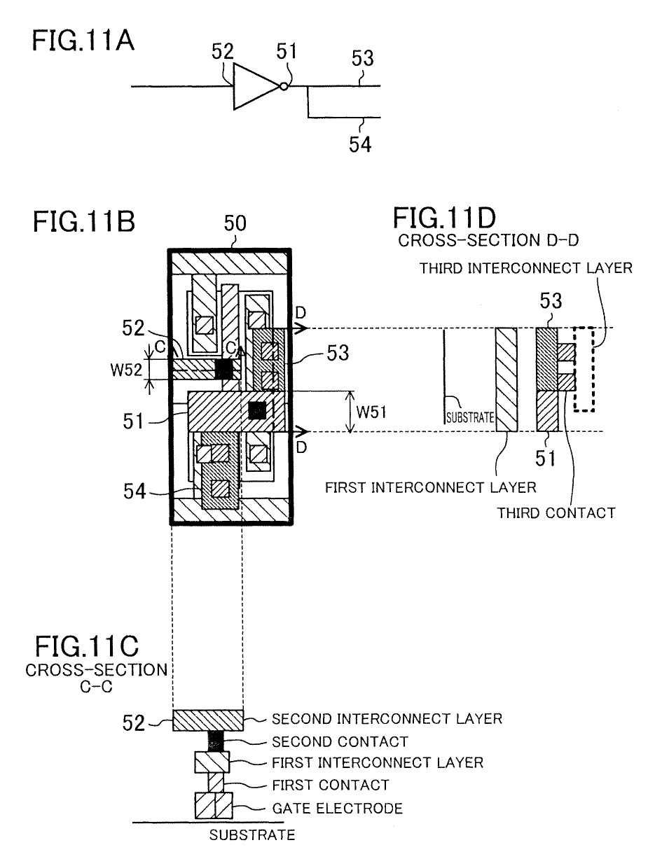

FIGS. 10A-10D illustrate the detailed structure of the standard cells 10 and 20 shown in FIG. 9. FIG. 10A is a logical diagram. FIG. 10B is a top view. FIG. 10C is a cross-sectional view taken along the line B-B of FIG. 10B. FIG. 10D is a cross-sectional view taken along the line A-A of FIG. 10B. FIGS. 11A-11C illustrate the structure of the standard cell 50 shown in FIG. 9. FIG. 11A is a logical diagram. FIG. 11B is a top view. FIG. 11C is a cross-sectional view taken along the line C-C of FIG. 11B. FIG. 11D is a cross-sectional view taken along the line D-D of FIG. 11B.

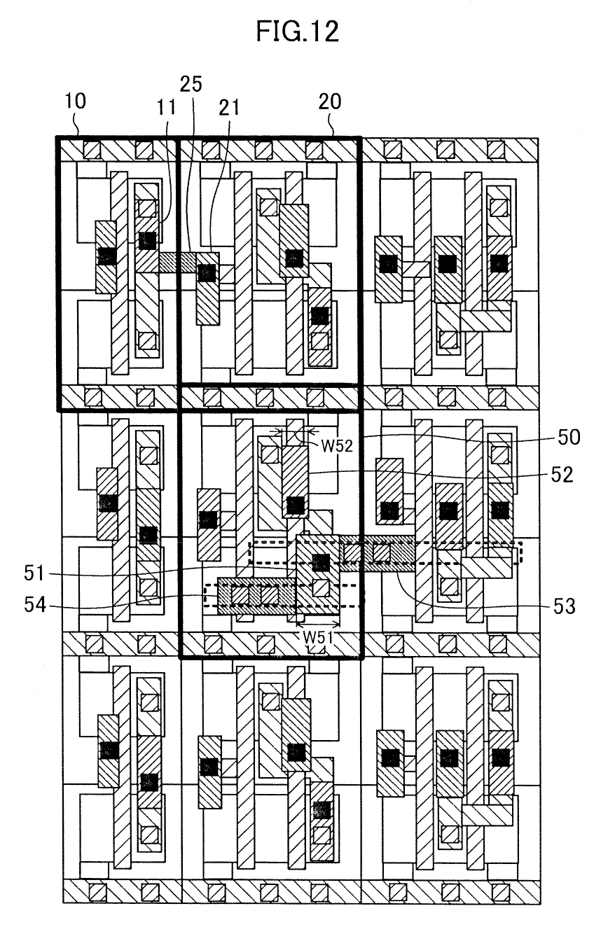

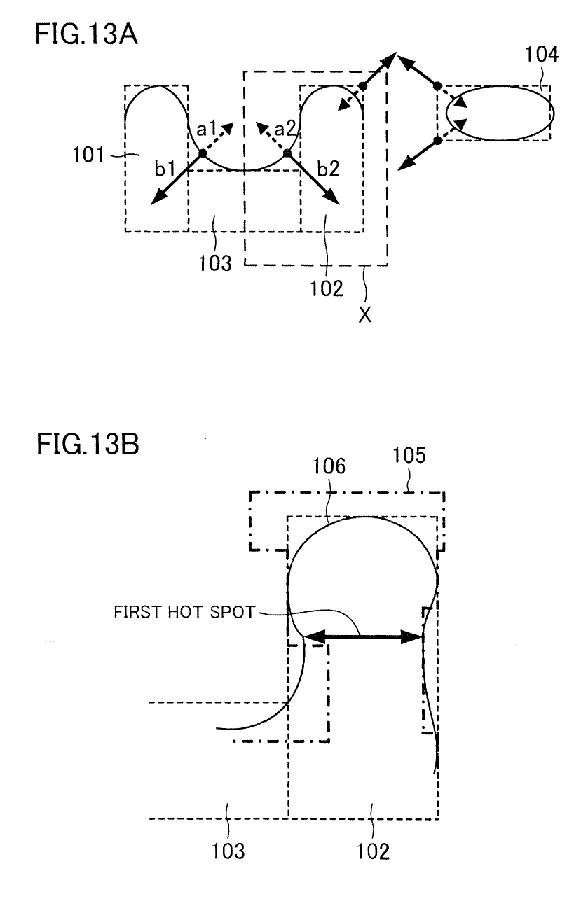

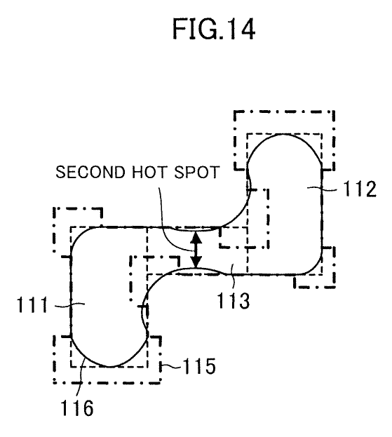

FIG. 12 illustrates another example layout structure of an actual semiconductor integrated circuit device where the interconnect structure according to the embodiments is used in standard cells. In FIG. 12, similar to FIG. 9, standard cells indicated by rectangular frames are arranged in a matrix and form a predetermined logic. The standard cells employing the above-described embodiments are surrounded by thick frames. Specifically, two left standard cells 10 and 20 in the uppermost row employ the interconnect structure shown in FIG. 1. The central standard cell 50 in the central row employs the interconnect structure shown in FIG. 7. In FIG. 12, the same reference characters as those shown in FIGS. 1 and 7 are used to represent equivalent elements.

While in FIGS. 9 and 12, examples have been described where the standard cells employ the interconnect structures shown in FIGS. 1 and 7, the other interconnect structures described in the above-described embodiments may be used as the standard cells in a layout structure of an actual semiconductor integrated circuit device.

The present disclosure provides an interconnect structure of terminals of standard cells, which is less likely to cause a hot spot, thereby reducing the TAT and improving the manufacturing yield of a semiconductor integrated circuit device. Therefore, the present disclosure is advantageous in reducing the period and costs of manufacturing an LSI.

What is claimed is:

1. A semiconductor integrated circuit device comprising:
a first standard cell;
a second standard cell adjacent to the first standard cell in a first direction;
an output terminal portion provided as an output terminal of the first standard cell to extend in a second direction orthogonal to the first direction;
an input terminal portion provided as an input terminal of the second standard cell to extend in the second direction; and
an interconnect provided to extend in the first direction to electrically connect the output terminal portion to the input terminal portion, wherein
the output terminal portion, the input terminal portion, and the interconnect are formed in a same metal interconnect layer,
the output terminal portion extends in a first sub-direction of the second direction from a region connected to the interconnect, but not in a second sub-direction opposite to the first sub-direction, and
the input terminal portion extends in the second sub-direction of the second direction from a region connected to the interconnect, but not in the first sub-direction.

2. The device of claim 1, wherein
at least one of the output terminal portion or the input terminal portion includes a protrusion formed to protrude in a sub-direction of the first direction opposite to the interconnect.

3. The device of claim 1, wherein
the output terminal portion is an output terminal of the first standard cell, which is closest to the second standard cell, and
the input terminal portion is an input terminal of the second standard cell, which is closest to the first standard cell.

4. The device of claim 1, wherein
an interconnect width of the interconnect is greater than or equal to terminal widths of the output terminal portion and the input terminal portion.

5. A terminal structure of a standard cell, the structure comprising:
an input terminal portion provided as an input terminal of the standard cell to extend in a first direction; and
an output terminal portion provided as an output terminal of the standard cell to extend in the first direction, wherein
the input terminal portion overlaps the output terminal portion in an overlapping region as viewed along a second direction orthogonal to the first direction,
the input terminal portion extends in a first sub-direction of the first direction from the overlapping region, but not in a second sub-direction opposite to the first sub-direction, and
the output terminal portion extends in the second sub-direction of the first direction from the overlapping region, but not in the first sub-direction.

6. The terminal structure of claim 5, wherein
at least one of the input terminal portion or the output terminal portion includes a protrusion formed to protrude toward a center of the standard cell in the second direction.

7. The terminal structure of claim 5, wherein
the input terminal portion is an input terminal of the standard cell, which is closest to one side of a frame in the second direction, and
the output terminal portion is an output terminal of the standard cell, which is closest to the other side of the frame in the second direction.

8. A semiconductor integrated circuit device comprising:
a standard cell;
an output terminal portion provided as an output terminal of the standard cell to extend in a first direction;
an input terminal portion provided as an input terminal of the standard cell to extend in the first direction;
a first interconnect connected to the output terminal portion, and provided to extend in a first sub-direction of a second direction orthogonal to the first direction from the output terminal portion; and
a second interconnect connected to the output terminal portion, and provided to extend in a second sub-direction of the second direction, which is opposite to the first sub-direction, from the output terminal portion, wherein
the output terminal portion, the input terminal portion, and the first and second interconnects are formed in a same metal interconnect layer,
the first interconnect does not overlap the second interconnect as viewed along the second direction, and
a terminal width of the output terminal portion between a portion connected to the first interconnect and a portion connected to the second interconnect is greater than a terminal width of the input terminal portion.

9. A semiconductor integrated circuit device comprising:
a first standard cell;
a second standard cell adjacent to the first standard cell in a first direction;
an output terminal portion provided as an output terminal of the first standard cell to extend in a second direction orthogonal to the first direction;
an input terminal portion provided as an input terminal of the second standard cell to extend in the second direction; and
an interconnect provided to extend in the first direction to electrically connect the output terminal portion to the input terminal portion, wherein
the output terminal portion, the input terminal portion, and the interconnect are formed in a same metal interconnect layer,
the output terminal portion is located in a same position and has a same length as the input terminal portion in the second direction, and
the interconnect has an interconnect width which is equal to lengths of the output terminal portion and the input terminal portion, and is located in a same position as the output terminal portion and the input terminal portion in the second direction.

10. The device of claim 9, wherein
at least one of the output terminal portion or the input terminal portion includes a protrusion formed to protrude in a sub-direction of the first direction opposite to the interconnect.
